(19) United States
(12) Patent Application Publication
(10) Pub. No.: US 2026/0293357 A1
(43) Pub. Date: Sep. 24, 2026

(54) SOLID-STATE IMAGING DEVICE AND ELECTRONIC APPARATUS

(71) Applicant: SONY SEMICONDUCTOR SOLUTIONS CORPORATION, KANAGAWA (JP)

(72) Inventors: TAKAYUKI KAI, KANAGAWA (JP); HAJIME YAMAGISHI, KANAGAWA (JP); KENTA ONO, KANAGAWA (JP)

(21) Appl. No.: 19/480,118

(22) PCT Filed: May 9, 2024
(86) PCT No.: PCT/JP2024/017202

§ 371 Date: Oct. 30, 2025

(30) Foreign Application Priority Data
May 22, 2023 (JP) 2023-084063

(51) Int. Cl. H10F 39/00; H04N 25/79

(52) U.S. Cl. CPC H10F 39/811; H04N 25/79

(57) ABSTRACT

The present disclosure relates to a solid-state imaging device and an electronic apparatus in which electromigration due to current concentration in a wiring line directly below a pad can be suppressed. A solid-state imaging device includes a first substrate including a first pad and a first semiconductor substrate and a second substrate including a second pad and a second semiconductor substrate. The solid-state imaging device is configured such that the first substrate and the second substrate are layered in a vertical direction, and a plurality of through electrodes penetrating the first semiconductor substrate and electrically connecting the first pad and the second pad are disposed in a ring shape in a plan view. The present disclosure is applicable to, for example, a solid-state imaging device constituted of a layered structure of three substrates or the like.

### TECHNICAL FIELD

The present disclosure relates to a solid-state imaging device and an electronic apparatus, and particularly relates to a solid-state imaging device and an electronic apparatus in which electromigration due to current concentration in a wiring line directly below a pad can be suppressed.

### BACKGROUND ART

PTL 1 discloses a solid-state imaging device obtained by bonding a first substrate on which a photoelectric conversion element and a transfer transistor of each pixel are disposed and a second substrate on which an amplification transistor, a reset transistor, and the like of the pixel are disposed. In the solid-state imaging device of PTL 1, a pad for connecting the solid-state imaging device to an external terminal and an opening for exposing the pad are formed in the first substrate, and the pad is connected to wiring lines directly below the pad via a plurality of vias.

### CITATION LIST

### Patent Literature

PTL 1: JP 2017-201709 A

### SUMMARY

### Technical Problem

In a case in which a wiring line is provided directly below a pad, electromigration due to current concentration is a concern, particularly in a pad that supplies power supply voltage.

The present disclosure has been made in view of such circumstances, and an object thereof is to make it possible to suppress electromigration due to current concentration in a wiring line directly below a pad.

### Solution to Problem

A solid-state imaging device according to a first aspect of the present disclosure includes a first substrate including a first pad and a first semiconductor substrate and a second substrate including a second pad and a second semiconductor substrate. The solid-state imaging device is configured such that the first substrate and the second substrate are layered in a vertical direction, and a plurality of through electrodes penetrating the first semiconductor substrate and electrically connecting the first pad and the second pad are disposed in a ring shape in a plan view.

An electronic apparatus according to a second aspect of the present disclosure includes a solid-state imaging device including a first substrate including a first pad and a first semiconductor substrate and a second substrate including a second pad and a second semiconductor substrate. The solid-state imaging device is configured such that the first substrate and the second substrate are layered in a vertical direction, and a plurality of through electrodes penetrating the first semiconductor substrate and electrically connecting the first pad and the second pad are disposed in a ring shape in a plan view.

In the first and second aspects of the present disclosure, a first substrate including a first pad and a first semiconductor substrate and a second substrate including a second pad and a second semiconductor substrate are provided, the solid-state imaging device is configured such that the first substrate and the second substrate are layered in a vertical direction, and a plurality of through electrodes penetrating the first semiconductor substrate and electrically connecting the first pad and the second pad are disposed in a ring shape in a plan view.

The solid-state imaging device and the electronic apparatus may be independent devices or modules incorporated in other devices.

### BRIEF DESCRIPTION OF DRAWINGS

FIG. 1 is a diagram depicting a schematic configuration of a solid-state imaging device to which the technology of the present disclosure is applied.

FIG. 2 is a diagram depicting a circuit configuration example of a pixel.

FIG. 3 is a perspective view of the solid-state imaging device configured to have a layered structure of three substrates.

FIG. 4 is a detailed cross-sectional view of the solid-state imaging device having a three-layer structure.

FIG. 5 is a plan view depicting a positional relationship between pads of a second substrate and a third substrate.

FIG. 6 is a cross-sectional view of a layered Structure of a solid-state imaging device of a comparative example.

FIG. 7 is a plan view depicting a positional relationship between pads of the solid-state imaging device of the comparative example.

FIG. 8 is a cross-sectional view of a three-layer structure according to a modification of the solid-state imaging device.

FIG. 9 is a plan view depicting an arrangement of a plurality of through electrodes according to a modification of the solid-state imaging device.

FIG. 10 is a cross-sectional view for describing variations of a pad structure.

FIG. 11 is a cross-sectional view for describing variations of the pad structure.

FIG. 12 is a cross-sectional view for describing variations of the pad structure.

FIG. 13 is a diagram for describing a usage example of an image sensor.

FIG. 14 is a block diagram depicting a configuration example of an imaging device as an electronic apparatus to which the technology of the present disclosure is applied.

FIG. 15 is a block diagram depicting an example of a schematic configuration of a vehicle control system.

FIG. 16 is an explanatory view depicting an example of an installation position of an outside-vehicle information detecting unit and an imaging section.

### DESCRIPTION OF EMBODIMENTS

Hereinafter, modes for carrying out the technology of the present disclosure (hereinafter, referred to as embodiments) will be described with reference to the drawings. Description will be made in the following order.
1. Schematic Configuration Example of Solid-State Imaging Device
2. Pixel Circuit Configuration Example
3. Three-Layer Structure Configuration Example
4. Plan View of Pad Region
5. Comparison with Other Layered Structure of Pad Arrangement
6. Modification
7. Variation Examples of Pad Structure
8. Summary of Pad Structure of Present Disclosure
9. Usage Example of Image Sensor
10. Application Example to Electronic Apparatus
11. Application to General Light Detection Device
12. Application Example to Mobile Body

Note that, in the drawings referenced in the following description, the same or similar portions are denoted using the same or similar reference signs, and redundant description thereof will be omitted as appropriate. The drawings are schematic, and a relationship between a thickness and a planar dimension, a ratio of a thickness of each layer, and the like differ from actual ones. Further, the drawings may include portions having dimensional relationships or ratios that differ between the drawings.

Further, definitions of directions such as up and down in the following description are merely definitions for convenience of description, and do not limit the technical idea of the present disclosure. For example, up and down are converted to and read as left and right when a target is observed upon rotation by 90°, and up and down are read inverted when the target is observed upon rotation by 180°.

Hereinafter, an embodiment of a solid-state imaging device to which the present technology is applied will be described, but the present technology can be applied to general semiconductor devices.

### 1. Schematic Configuration Example of Solid-State Imaging Device

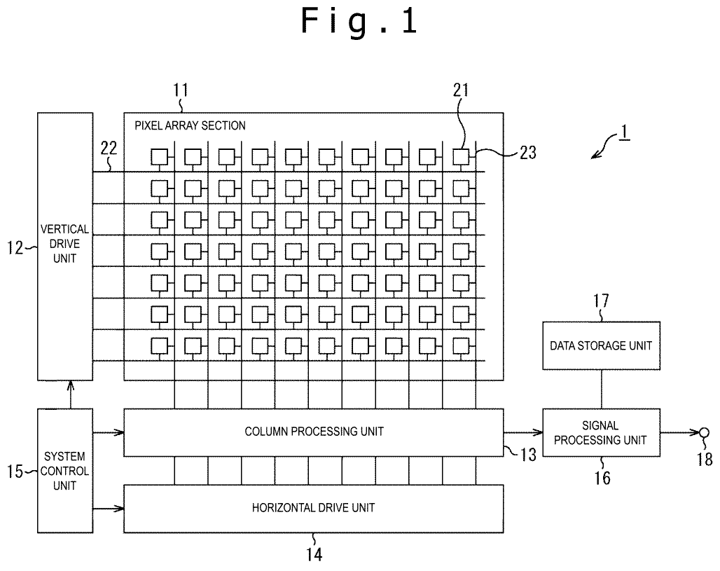

FIG. 1 is a diagram depicting a schematic configuration of a solid-state imaging device to which the technology of the present disclosure is applied.

FIG. 1 depicts a solid-state imaging device 1 having a configuration of a complementary metal oxide semiconductor (CMOS) image sensor that is a type of solid-state imaging device of an X-Y address system, for example. The CMOS image sensor is an image sensor manufactured by applying or partially using a CMOS process.

The solid-state imaging device 1 includes a pixel array section 11 and a peripheral circuit section. The peripheral circuit section includes, for example, a vertical drive unit 12, a column processing unit 13, a horizontal drive unit 14, and a system control unit 15.

The solid-state imaging device 1 further includes a signal processing unit 16 and a data storage unit 17. The signal processing unit 16 and the data storage unit 17 may be mounted on the same substrate as that of the pixel array section 11, the vertical drive unit 12, and the like, or may be disposed on another substrate. Further, each processing at the signal processing unit 16 and the data storage unit 17 may be executed by an external signal processing unit provided in a semiconductor chip different from that of the solid-state imaging device 1, such as, for example, a digital signal processor (DSP) circuit.

The pixel array section 11 has a configuration in which a plurality of pixels 21 are two-dimensionally disposed in a matrix shape in a row direction and a column direction. Here, the row direction refers to a pixel row of the pixel array section 11, that is, an array direction in a horizontal direction, and the column direction refers to a pixel column of the pixel array section 11, that is, an array direction in a vertical direction.

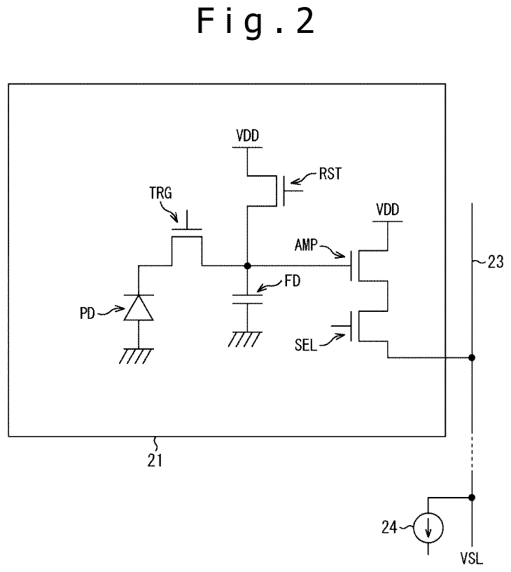

The pixel 21 includes a photoelectric conversion section that generates and accumulates charges corresponding to an amount of received light, and a plurality of pixel transistors (so-called MOS transistors). Note that a specific circuit configuration example of the pixel 21 will be described below with reference to FIG. 2.

Further, in the pixel array section 11, a pixel drive wiring line 22 serving as a row signal line is wired in the row direction for each pixel row, and a vertical signal line 23 serving as a column signal line is wired in the column direction for each pixel column. The pixel drive wiring line 22 transmits a drive signal for driving when a signal is read from the pixel 21. In FIG. 1, the pixel drive wiring line 22 is depicted as one wiring line, but is not limited to one wiring line. One end of the pixel drive wiring line 22 is connected to an output end corresponding to the row of the vertical drive unit 12.

The vertical drive unit 12 is configured by a shift register, an address decoder, and the like, and drives each pixel of the pixel array section 11 simultaneously for all pixels, in units of rows, or the like. The vertical drive unit 12 constitutes a drive unit that controls the operation of each pixel of the pixel array section 11 together with the system control unit 15. Although illustration of a specific configuration is omitted, the vertical drive unit 12 typically includes two scanning systems of a readout scanning system and a sweep-out scanning system.

The readout scanning system sequentially and selectively scans, in units of rows, the pixels 21 of the pixel array section 11 in order to read out signals from the pixels 21. The signal read from the pixel 21 is an analog signal. The sweep-out scanning system performs sweep-out scanning on a readout row on which readout scanning is to be performed by the readout scanning system, preceding the readout scanning by an exposure time period.

The sweep-out scanning by this sweep-out scanning system resets the photoelectric conversion section of each pixel 21 by sweeping out unnecessary charges from the photoelectric conversion section of the pixel 21 of the readout row. Then, by sweeping out (resetting) unnecessary charges by the sweep-out scanning system, a so-called electronic shutter operation is performed. Here, the electronic shutter operation refers to an operation of discarding the charge of the photoelectric conversion section and newly starting exposure (starting accumulation of charge).

The signal read out by the readout operation performed by the readout scanning system corresponds to the amount of light received after the immediately preceding readout operation or electronic shutter operation. A time period from a readout timing at which the immediately preceding readout operation is performed or a sweep-out timing at which the electronic shutter operation is performed to a readout timing at which the current readout operation is performed is the exposure time period of the pixel 21.

A signal output from each pixel 21 of a pixel row selectively scanned by the vertical drive unit 12 is input to the column processing unit 13 through each of the vertical signal lines 23 for each pixel column. The column processing unit 13 performs, for each pixel column of the pixel array section 11, predetermined signal processing on a signal output from each pixel 21 of the selected row through the vertical signal line 23, and temporarily holds the pixel signal after the signal processing.

Specifically, the column processing unit 13 performs at least noise removal processing, for example, correlated double sampling (CDS) processing or double data sampling (DDS) processing, as the signal processing. For example, the CDS processing removes reset noise and fixed pattern noise specific to the pixel caused by threshold variations of the amplification transistor in the pixel. The column processing unit 13 may have, for example, an analog-to-digital (AD) conversion function in addition to the noise removal processing, and may convert an analog pixel signal into a digital signal and output the digital signal.

The horizontal drive unit 14 is configured by a shift register, an address decoder, and the like, and sequentially selects a unit circuit corresponding to the pixel column of the column processing unit 13. By the selective scanning by this horizontal drive unit 14, pixel signals subjected to the signal processing for each unit circuit in the column processing unit 13 are sequentially output.

The system control unit 15 is configured by a timing generator that generates various timing signals, and the like, and performs drive control of the vertical drive unit 12, the column processing unit 13, the horizontal drive unit 14, and the like on the basis of various timings generated by the timing generator.

The signal processing unit 16 has at least an arithmetic processing function, and performs various signal processing such as arithmetic processing on the pixel signal output from the column processing unit 13. The data storage unit 17 temporarily stores data necessary for the processing when the signal processing is performed in the signal processing unit 16. The pixel signal subjected to the signal processing in the signal processing unit 16 is converted into a predetermined format and output from an output unit 18 to outside of the device.

### 2. Pixel Circuit Configuration Example

FIG. 2 is a diagram depicting a circuit configuration example of one pixel 21 provided in the pixel array section 11.

In this example, one pixel 21 is configured to include a photodiode PD, a transfer transistor TRG, a floating diffusion region FD, a reset transistor RST, an amplification transistor AMP, and a selection transistor SEL. The transfer transistor TRG, the reset transistor RST, the amplification transistor AMP, and the selection transistor SEL are configured by an N-type MOS transistor (MOS FET), for example.

The photodiode PD is a photoelectric conversion section provided in the pixel 21, receives light from a subject, generates a charge according to the amount of received light by photoelectric conversion, and accumulates the charge. In the photodiode PD, an anode terminal is grounded and a cathode terminal is connected to the floating diffusion region FD via the transfer transistor TRG.

The transfer transistor TRG is provided between the photodiode PD and the floating diffusion region FD, and when turned on by a transfer drive signal supplied to a gate thereof, the transfer transistor TRG transfers the charge accumulated in the photodiode PD to the floating diffusion region FD.

The floating diffusion region FD is a voltage conversion section that converts the charge transferred from the photodiode PD via the transfer transistor TRG into an electric signal, for example, a voltage signal, and outputs the electric signal. The floating diffusion region FD is also connected to a source of the reset transistor RST and a gate of the amplification transistor AMP.

When the reset transistor RST is turned on by a reset drive signal supplied to a gate thereof, the charge accumulated in the floating diffusion region FD is discharged to a drain (constant voltage source VDD), and the potential of the floating diffusion region FD is reset.

The amplification transistor AMP outputs a pixel signal corresponding to the potential of the floating diffusion region FD. That is, the amplification transistor AMP constitutes a source follower circuit together with a constant current source 24 connected via the vertical signal line 23, and a pixel signal VSL indicating a level corresponding to the charge accumulated in the floating diffusion region FD is output from the amplification transistor AMP to the column processing unit 13 (FIG. 1) via the selection transistor SEL. The constant current source 24 is provided in, for example, the column processing unit 13.

The selection transistor SEL is connected between a source of the amplification transistor AMP and the vertical signal line 23, and a selection drive signal is supplied to a gate of the selection transistor SEL. When turned on by the selection drive signal, the selection transistor SEL is brought into a conductive state, and the pixel 21 in which the selection transistor SEL is provided is brought into a selected state. When the pixel 21 is brought into the selected state, the pixel signal VSL output from the amplification transistor AMP is read out to the column processing unit 13 via the vertical signal line 23.

The transfer drive signal, the reset drive signal, and the selection drive signal supplied to the gates of the transfer transistor TRG, the reset transistor RST, and the selection transistor SEL are transmitted from the vertical drive unit 12 via a row signal line corresponding to the pixel drive wiring line 22 in FIG. 1. The transfer drive signal, the reset drive signal, and the selection drive signal are pulse signals in which a high-level state is an active state (on state) and a low-level state is a non-active state (off state).

The pixel 21 has a circuit configuration as described above.

Note that the circuit configuration of FIG. 2 is an example of a pixel circuit that can be used in the pixel array section 11, and other circuit configurations can also be used. For example, each pixel 21 can have a shared pixel structure in which a plurality of pixels share a readout circuit. In a case in which a shared pixel structure is adopted as the pixel circuit, a configuration can be adopted in which, for example, the floating diffusion region FD, the reset transistor RST, the amplification transistor AMP, and the selection transistor SEL are shared by four (2×2) pixels in which two pixels are disposed in each of the row direction and the column direction, and the photodiode PD and the transfer transistor TRG are disposed in a pixel unit. Note that the number of pixels in the shared unit is not limited to four.

The solid-state imaging device 1 realizes circuits such as the pixel array section 11, the vertical drive unit 12, the column processing unit 13, the horizontal drive unit 14, the system control unit 15, the signal processing unit 16, and the data storage unit 17 depicted in FIG. 1 and FIG. 2, for example, in a layered structure in which three substrates are layered.

### 3. Three-Layer Structure Example

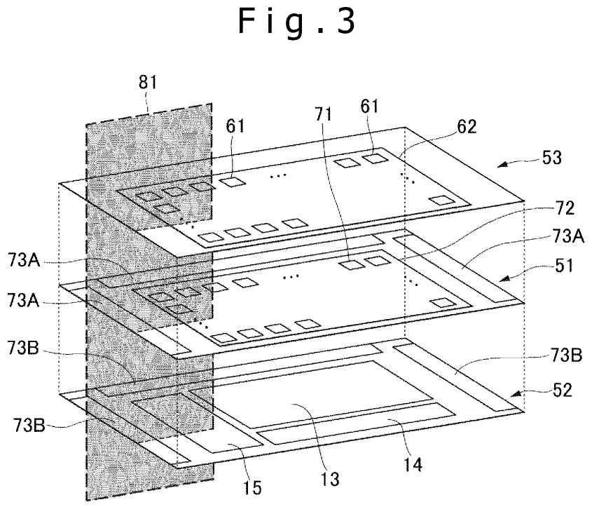

FIG. 3 is a perspective view depicting a schematic configuration example of the solid-state imaging device 1 configured with a layered structure of three substrates.

The solid-state imaging device 1 is configured by layering three substrates of a third substrate 53, a first substrate 51, and a second substrate 52 in this order from an incident surface side of incident light. The third substrate 53 and the second substrate 52 are disposed facing each other with the first substrate 51 interposed therebetween.

A light-receiving region 62 in which light-receiving pixels 61 are two-dimensionally disposed in a matrix is formed in a central portion of the third substrate 53. The light-receiving pixels 61 are part of the pixels 21 and each includes, for example, the photodiode PD and the transfer transistor TRG in the pixel circuit depicted in FIG. 2.

In the first substrate 51, a readout region 72 in which readout circuits 71 are two-dimensionally disposed in a matrix is formed in a central portion corresponding to the light-receiving region 62 of the third substrate 53. The readout circuits 71 are part of the pixels 21 and each includes, for example, the floating diffusion region FD, the reset transistor RST, the amplification transistor AMP, the selection transistor SEL, and the like in the pixel circuit depicted in FIG. 2.

Further, in the first substrate 51, a pad region 73A is formed in an outer peripheral portion of at least one of four sides of the first substrate 51 having a quadrangular shape, in a region outward of the readout region 72. In the example of FIG. 3, the pad region 73A is formed in the outer peripheral portion of three of the four sides of the first substrate 51. The pad region 73A includes an electrode pad electrically connected to an external device via wire bonding or the like, and the electrode pad inputs and outputs power supply voltage and signals.

In the second substrate 52, the column processing unit 13, the horizontal drive unit 14, the system control unit 15, and the like, for example, are formed in a central portion corresponding to the readout region 72 of the first substrate 51. Further, in the second substrate 52, a pad region 73B is formed in a region corresponding to the pad region 73A of the first substrate 51. The pad region 73B includes an electrode pad electrically connected to the pad region 73A of the first substrate 51, and the electrode pad inputs and outputs power supply voltage and signals from and to the first substrate 51.

The third substrate 53 and the first substrate 51 are electrically connected to each other via, for example, a through via, metal bonding of Cu-Cu, or the like. Similarly, the first substrate 51 and the second substrate 52 are electrically connected to each other via, for example, a through via, metal bonding of Cu-Cu, or the like.

As described above, the solid-state imaging device 1 is configured by layering the three substrates of the third substrate 53, the first substrate 51, and the second substrate 52, thereby making it possible to form the solid-state imaging device 1 with a chip size equivalent to that in the related art, even in a case where the number of the pixels or the pixel circuits is increased. Alternatively, in the case of an equivalent number of pixels or pixel circuits as that in the related art, it is possible to provide the solid-state imaging device 1 with a further reduced chip size.

Note that the circuit arrangement of each substrate described in FIG. 3 is merely an example, and which circuits are disposed on the third substrate 53, the first substrate 51, and the second substrate 52 is not particularly limited. For example, the vertical drive unit 12 not illustrated in FIG. 3 may be disposed on the first substrate 51 or may be disposed on the second substrate 52. The same applies to the signal processing unit 16, the data storage unit 17, and the like.

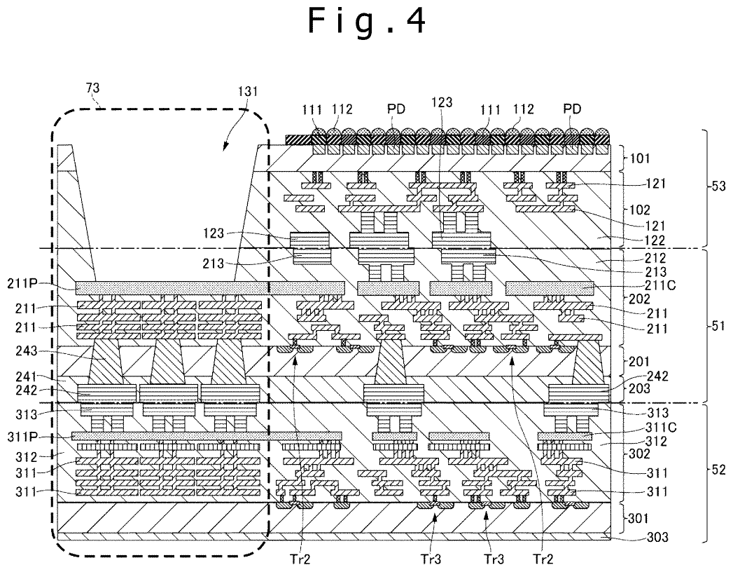

Next, a detailed cross-sectional structure of the three-layer structure of the third substrate 53, the first substrate 51, and the second substrate 52 will be described with reference to FIG. 4.

FIG. 4 is a cross-sectional view of the third substrate 53, the first substrate 51, and the second substrate 52 taken along a plane 81 in FIG. 3.

The solid-state imaging device 1 is configured by layering the third substrate 53, the first substrate 51, and the second substrate 52 in this order from the incident surface side of incident light. In FIG. 4, an upper side of the solid-state imaging device 1 is the light incident surface side on which incident light is incident, and a lower side of the solid-state imaging device 1 corresponds to a back surface of the solid-state imaging device 1 as a semiconductor chip. In FIG. 4, a bonding surface between the third substrate 53 and the first substrate 51 and a bonding surface between the first substrate 51 and the second substrate 52 are indicated by dot-dash lines. A pad region 73 at the right end of the solid-state imaging device 1 in FIG. 4 is a region corresponding to the pad regions 73A and 73B in FIG. 3.

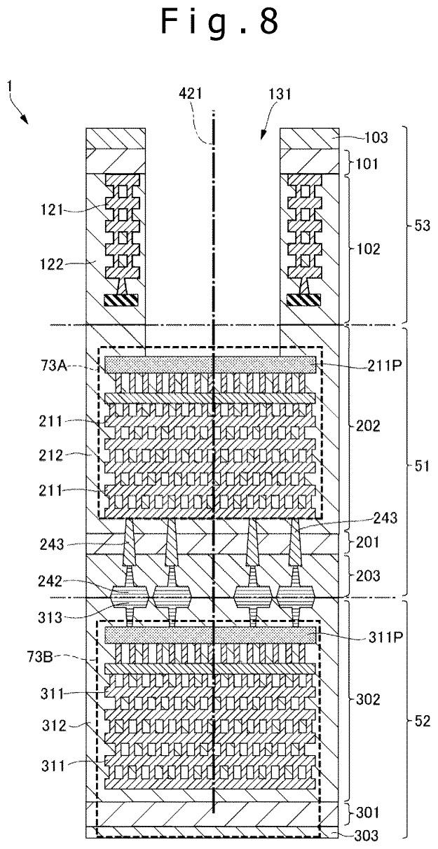

The third substrate 53 includes a semiconductor substrate 101 in which, for example, silicon (Si) is used as a semiconductor. The photodiode PD, which is a photoelectric conversion element, is formed in a pixel unit in the semiconductor substrate 101. In the drawing, a color filter 111 and an on-chip lens 112 are formed for each pixel on a light incident surface side of the semiconductor substrate 101, which is the upper side. Although not illustrated in FIG. 4, a planarization film 103 (FIG. 8) is formed between the semiconductor substrate 101 and the color filter 111.

A wiring layer 102 including a plurality of layers of metal wiring lines 121 and an insulating layer 122 is formed on a circuit formation surface side of the semiconductor substrate 101, which is a lower side in the drawing, on a side opposite to the light incident surface side. In the example of FIG. 4, three layers of the metal wiring lines 121 are formed, but the number of layers of the metal wiring lines 121 is not limited. Further, a plurality of bonding electrodes 123 are formed on a bonding surface with the first substrate 51, which is a lower surface of the wiring layer 102. The bonding electrode 123 is metal-bonded (for example, Cu-Cu bonded) to a bonding electrode 213 of the first substrate 51, and electrically connects the third substrate 53 and the first substrate 51. As materials of the metal wiring line 121 and the bonding electrode 123, for example, copper (Cu), tungsten (W), aluminum (Al), gold (Au), or the like can be adopted. In the present embodiment, the metal wiring line 121 and the bonding electrode 123 are formed of copper. The insulating layer 122 is formed of, for example, an SiO2 film, a low dielectric constant insulating film (low-k film), an SiOC film, or the like. The insulating layer 122 may be constituted of a plurality of insulating films made of different materials.

The third substrate 53 includes an opening 131 extending through the semiconductor substrate 101 and the wiring layer 102 in the pad region 73, and a bonding wire or the like can be connected to a pad 211P formed in the pad region 73 of the first substrate 51.

The first substrate 51 includes a semiconductor substrate 201 in which, for example, silicon (Si) is used as a semiconductor. The first substrate 51 includes a wiring layer 202 on a front surface side of the semiconductor substrate 201, which is the third substrate 53 side, and a bonding layer 203 on a back surface side of the semiconductor substrate 201, which is the second substrate 52 side. The wiring layer 202 includes a plurality of layers of metal wiring lines 211 and an insulating layer 212. In the example of FIG. 4, five layers of the metal wiring lines 211 are formed, but the number of layers of the metal wiring lines 211 is not limited. A plurality of the bonding electrodes 213 are formed on a bonding surface with the third substrate 53, which is an upper surface of the wiring layer 202. The bonding electrodes 213 are metal-bonded to the bonding electrodes 123 of the third substrate 53, and electrically connect the third substrate 53 and the first substrate 51.

In the first substrate 51, among the plurality of layers of the metal wiring lines 211, metal wiring lines 211C of an uppermost layer closest to the third substrate 53 are formed of a material different from that of the metal wiring lines 211 of the four lower layers. As materials of the metal wiring lines 211 and the bonding electrodes 213, for example, copper (Cu), tungsten (W), aluminum (Al), gold (Au), or the like can be adopted. For example, the four layers of the metal wiring lines 211 and the bonding electrodes 213 are formed of copper, and the metal wiring lines 211C of the uppermost layer are formed of aluminum. The insulating layer 212 is formed of, for example, an SiO2 film, a low dielectric constant insulating film (low-k film), a SiOC film, or the like. The insulating layer 212 may be constituted of a plurality of insulating films made of different materials. Among the metal wiring lines 211C of the uppermost layer, the pad 211P formed in the pad region 73 is an electrode pad formed in the pad region 73A of the first substrate 51 in FIG. 3. The opening 131 of the third substrate 53 is located on an upper surface of the pad 211P, and the pad 211P is exposed.

The bonding layer 203 formed on the back surface side of the semiconductor substrate 201, which is the second substrate 52 side, includes an insulating layer 241 and a plurality of bonding electrodes 242. The bonding electrodes 242 are metal-bonded to bonding electrodes 313 of the second substrate 52, and electrically connect the first substrate 51 and the second substrate 52. Materials of the insulating layer 241 and the bonding electrodes 242 are similar to those of the insulating layer 212 and the bonding electrodes 213.

A plurality of through electrodes (through-silicon vias; TSVs) 243 extending through the semiconductor substrate 201 are formed in a predetermined region of the semiconductor substrate 201 of the first substrate 51. The through electrodes 243 directly connect the metal wiring lines 211 of the wiring layer 202 on the third substrate 53 side and the bonding electrodes 242 of the bonding layer 203 on the second substrate 52 side, and electrically connect the third substrate 53 side and the second substrate 52 side of the first substrate 51. A plurality of MOS transistors Tr2 constituting a logic circuit are formed at an interface of a front surface of the semiconductor substrate 201.

The second substrate 52 includes a semiconductor substrate 301 in which, for example, silicon (Si) is used as a semiconductor, and a wiring layer 302 on a front surface side of the semiconductor substrate 301, which is the first substrate 51 side. A protective film 303 is formed on a back surface side of the semiconductor substrate 301 on a side opposite to the first substrate 51 side. The wiring layer 302 includes a plurality of layers of metal wiring lines 311 and an insulating layer 312. In the example of FIG. 4, six layers of the metal wiring lines 311 are formed, but the number of layers of the metal wiring lines 311 is not limited. A plurality of the bonding electrodes 313 are formed on a bonding surface with the first substrate 51, which is an upper surface of the wiring layer 302. The bonding electrodes 313 are metal-bonded to the bonding electrodes 242 of the first substrate 51, and electrically connect the first substrate 51 and the second substrate 52.

In the second substrate 52, among the plurality of layers of the metal wiring lines 311, metal wiring lines 311C of an uppermost layer closest to the first substrate 51 are formed of a material different from that of the metal wiring lines 311 of the five lower layers. As materials of the metal wiring lines 311 and the bonding electrodes 313, for example, copper (Cu), tungsten (W), aluminum (Al), gold (Au), or the like can be adopted. For example, the five layers of the metal wiring lines 311 and the bonding electrodes 313 are formed of copper, and the metal wiring lines 311C of the uppermost layer are formed of aluminum. The insulating layer 312 is formed of, for example, a SiO2 film, a low dielectric constant insulating film (low-k film), a SiOC film, or the like. The insulating layer 312 may be constituted of a plurality of insulating films made of different materials. Among the metal wiring lines 311C of the uppermost layer, a pad 311P formed in the pad region 73 is an electrode pad formed in the pad region 73B of the second substrate 52 in FIG. 3.

A plurality of MOS transistors Tr3 constituting a logic circuit are formed at an interface of the front surface of the semiconductor substrate 301 of the second substrate 52.

As described above, the solid-state imaging device 1 is configured by layering the third substrate 53, the first substrate 51, and the second substrate 52 in the vertical direction. In the pad region 73 formed in an outer peripheral portion of the solid-state imaging device 1, the opening 131 of the third substrate 53, the pad 211P of the first substrate 51, and the pad 311P of the second substrate 52 are disposed in regions Overlapping in a plan view.

### 4. Plan View of Pad Region

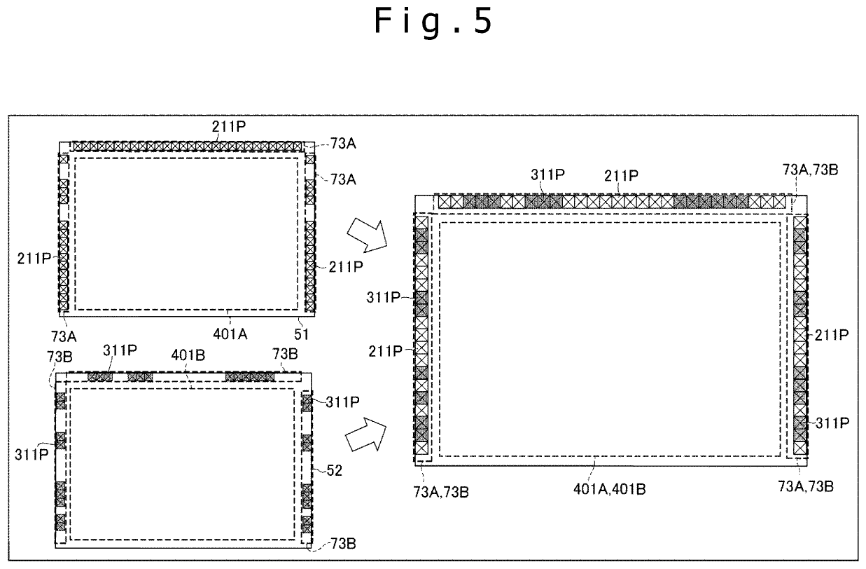

FIG. 5 is a plan view depicting a positional relationship between the pad region 73A of the first substrate 51 and the pad region 73B of the second substrate 52.

As depicted on the left side of FIG. 5, in the first substrate 51, the pad region 73A is disposed in a substrate outer peripheral portion, and a circuit region 401A is disposed on an inner side thereof. In the second substrate 52, the pad region 73B is disposed in the substrate outer peripheral portion, and a circuit region 401B is disposed on an inner side thereof. In a state in which the first substrate 51 and the second substrate 52 are layered as depicted on the right side of FIG. 5, a region where the pad region 73A and the pad region 73B overlap is the pad region 73 of the solid-state imaging device 1.

The pad region 73 of the solid-state imaging device 1 includes a first pad region in which both the pad 211P of the first substrate 51 and the pad 311P of the second substrate 52 are formed, a second pad region in which only the pad 211P of the first substrate 51 is formed, and a third pad region in which only the pad 311P of the second substrate 52 is formed.

The pad 211P of the first substrate 51 and the pad 311P of the second substrate 52 in the first pad region are utilized as substrate input/output terminals for a power supply voltage VDD1 and a signal SIG1 commonly used in the first substrate 51 and the second substrate 52, for example. The pad 211P of the first substrate 51 in the second pad region is utilized as a substrate input/output terminal for a power supply voltage VDD2 and a signal SIG2 used only in the first substrate 51, for example. The pad 311P of the second substrate 52 in the third pad region is utilized as, for example, a substrate input/output terminal for evaluating the second substrate 52 as a single unit, and is not utilized after layering.

Note that, in the plan view of a state in which the first substrate 51 and the second substrate 52 are layered on the right side of FIG. 5, in a case in which both the pad 211P of the first substrate 51 and the pad 311P of the second substrate 52 are formed, the pad 311P of the second substrate 52 is depicted. In the case in which both the pad 211P of the first substrate 51 and the pad 311P of the second substrate 52 are formed, the pad 211P of the first substrate 51 and the pad 311P of the second substrate 52 are connected to each other by a plurality of metal bonding portions or the like obtained by bonding the plurality of through electrodes 243 formed in the first substrate 51, the bonding electrodes 242 formed in the first substrate 51, and the bonding electrodes 313 formed in the second substrate 52 to each other, as depicted in FIG. 4.

As described above, in the solid-state imaging device 1, the pad regions 73A of the first substrate 51 and the pad regions 73B of the second substrate 52 are disposed in the vicinity of the outer peripheral portions of substrate regions having quadrangular shapes, the vicinity of the outer peripheral portions serving as the regions where the pat regions 73A and 73B overlap in a plan view, thereby enlarging the circuit regions 401A and 401B.

### 5. Comparison with Other Layered Structure of Pad Arrangement

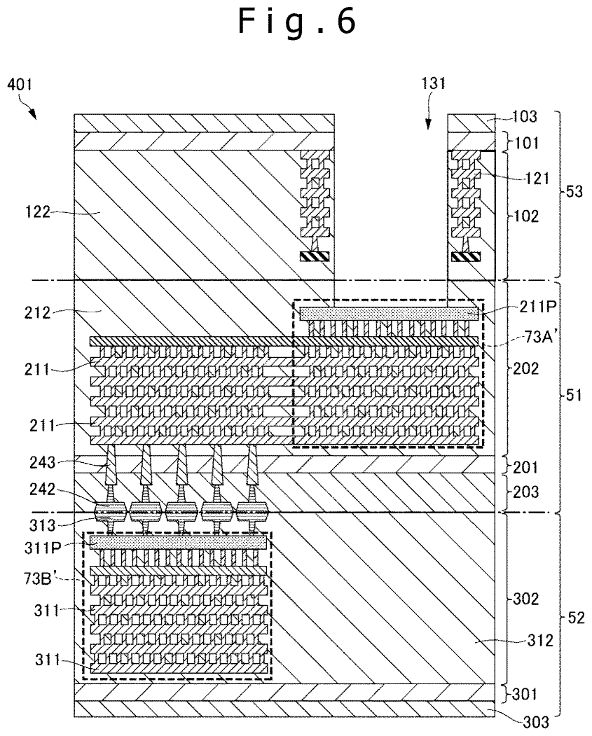

FIG. 6 is a layered structure cross-sectional view of a solid-state imaging device as a comparative example for comparison with the layered structure example of the pad region 73 of the solid-state imaging device 1.

In FIG. 6, portions corresponding to each component of the solid-state imaging device 1 depicted in FIG. 4 are denoted using the same reference signs, and description thereof will be omitted, as appropriate.

In a solid-state imaging device 401 of FIG. 6 depicted as the comparative example, a positional relationship between a pad region 73A′ in which the pad 211P is formed in the first substrate 51 and a pad region 73B′ in which the pad 311P is formed in the second substrate 52 differs from that of the solid-state imaging device 1. Specifically, the pad region 73A′ of the first substrate 51 and the pad region 73B′ of the second substrate 52 are not formed in regions overlapping in a plan view, and the pad region 73B′ of the second substrate 52 is disposed at a position shifted inward in a planar direction (toward the substrate center) from the pad region 73A′ of the first substrate 51.

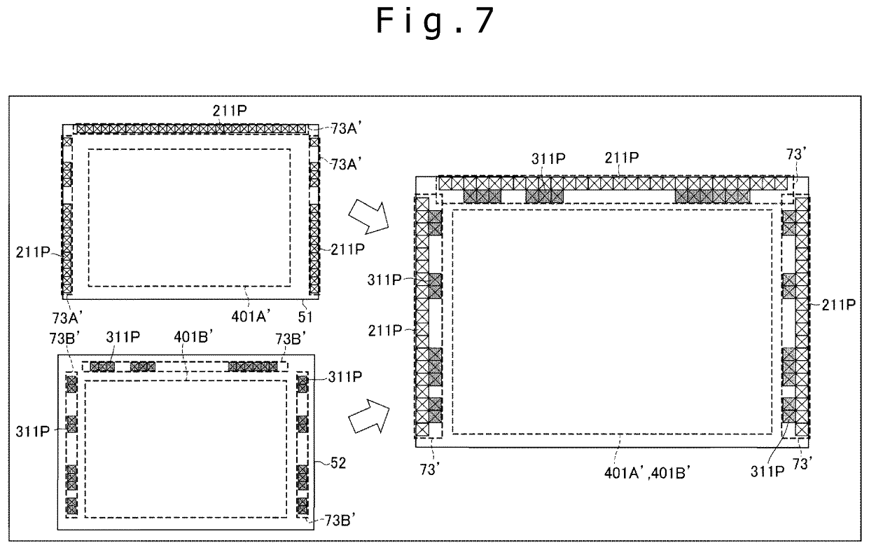

FIG. 7 is a plan view depicting a positional relationship between the pad region 73A′ of the first substrate 51 and the pad region 73B′ of the second substrate 52 of the solid-state imaging device 401 according to the comparative example.

As depicted on the left side of FIG. 7, the pad region 73A′ of the first substrate 51 is disposed in the substrate outer peripheral portion similarly to the pad region 73A of the solid-state imaging device 1, and a circuit region 401A′ is disposed therein. The pad region 73B′ of the second substrate 52 is disposed in a region not overlapping the pad region 73A′ of the first substrate 51 in a plan view and is disposed inward of the pad region 73A′ (toward the substrate center). In a state in which the first substrate 51 and the second substrate 52 are layered as depicted on the right side of FIG. 7, a pad region 73′ including the pad region 73A′ and the pad region 73B′ is a region wider than the pad region 73 of the solid-state imaging device 1, making the circuit regions 401A′ and 401B′ narrower than the circuit regions 401A and 401B of the solid-state imaging device 1.

As in the solid-state imaging device 401 of FIG. 6 and FIG. 7, in a case in which the pad region 73A′ of the first substrate 51 and the pad region 73B′ of the second substrate 52 are disposed in different regions in a plan view, at least the circuit region 401B′ of the second substrate 52 is a region narrower than the circuit region 401B of the solid-state imaging device 1, reducing a circuit area.

Further, in the solid-state imaging device 1, the pad 211P of the first substrate 51 and the pad 311P of the second substrate 52 can be directly electrically connected across a short distance in the vertical direction. However, in the solid-state imaging device 401, it is necessary to draw the metal wiring lines 211 in an L shape to make the connection. In a case in which the pads 211P and 311P are power supply pads that supply power supply voltage, an IR drop deteriorates due to the increase in a wiring line length of the metal wiring lines 211. In a case in which the pads 211P and 311P are signal pads that transmit signals, a signal delay deteriorates due to the increase in the wiring line length of the metal wiring lines 211.

Further, in a case in which the pad region 73A′ of the first substrate 51 and the pad region 73B′ of the second substrate 52 are at different positions, a probe card for measurement cannot be shared, making it necessary to prepare probe cards separately.

In contrast, as depicted in FIG. 4 and FIG. 5, according to the solid-state imaging device 401 in which the pad region 73A of the first substrate 51 and the pad region 73B of the second substrate 52 are disposed in regions overlapping in a plan view, the circuit regions 401A and 401B can be enlarged to a greater degree than in the solid-state imaging device 401. Further, wiring line routing for connecting the pad 211P of the first substrate 51 and the pad 311P of the second substrate 52 is reduced, and connection across a short distance can be achieved, thereby making it possible to significantly reduce the IR drop and reduce the signal delay. Center coordinates of the pad 211P of the first substrate 51 and the pad 311P of the second substrate 52 are the same, making it possible to share the probe card for measurement and realize cost reduction.

### 6. Modification

FIG. 8 is a cross-sectional view of a three-layer structure according to a modification of the solid-state imaging device 1.

In FIG. 8 as well, portions corresponding to those in the cross-sectional view depicted in FIG. 4 are denoted using the same reference signs, and description of common portions will be omitted, as appropriate.

In FIG. 4, the through electrodes 243 penetrating the semiconductor substrate 201 of the first substrate 51 and electrically connecting the pads 211P of the first substrate 51 and the pads 311P of the second substrate 52 are also disposed in a central portion of the opening 131 in a plan view.

In contrast, in the solid-state imaging device 1 according to the modification in FIG. 8, the through electrode 243 is not formed in the vicinity of a planar center 421 of the opening 131 indicated by a dash-dot line, and a plurality of the through electrodes 243 are densely formed in outer peripheral portions of the pad 211P and the pad 311P.

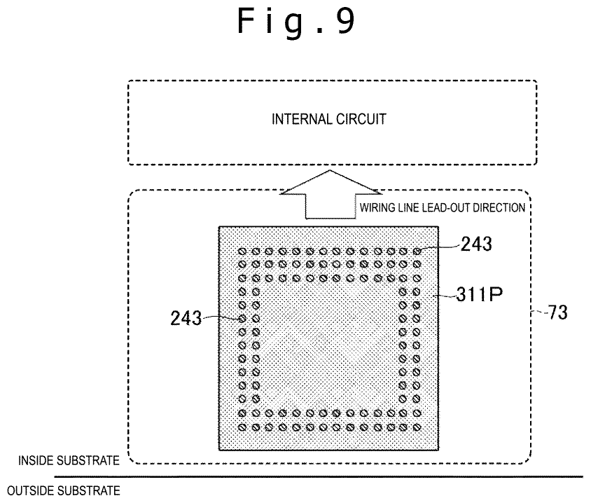

FIG. 9 is a plan view depicting an arrangement of the plurality of through electrodes 243 in the modification of the solid-state imaging device 1. FIG. 9 corresponds to a view of the plurality of through electrodes 243 and the pad 311P of the second substrate 52 from above the first substrate 51.

The plurality of through electrodes 243 penetrating the semiconductor substrate 201 of the first substrate 51 are not disposed in planar central portions of the pads 211P and 311P in a plan view, but are disposed in ring shapes along outer shapes of the pads 211P and 311P. The ring shape means a shape in which a central portion is an empty region in which the through electrode 243 is not disposed, and the empty region is surrounded by the through electrodes 243 disposed in a circular shape (including an elliptical shape) or a polygonal shape (for example, a quadrangular shape). When the plurality of through electrodes 243 are disposed evenly in a matrix including the planar central portions of the pads 211P and 311P, and the bonding wire is connected to a substantially central portion of the pad 211P, current flows in a concentrated manner through the plurality of through electrodes 243 near the central portion, resulting in a concern of electromigration due to the current concentration. That is, in a case in which a high-density current flows through the plurality of through electrodes 243 in the vicinity of the central portion for a long period of time, disconnection or a state close to disconnection may occur. As depicted in FIG. 9, the through electrodes 243 are not disposed in the planar central portions of the pads 211P and 311P, but are disposed in ring shapes at positions close to the outer peripheral portions, making it possible to disperse the current and suppress electromigration due to the current concentration. Further, it is possible to suppress electromagnetic noise caused by current concentration.

Further, regarding the number of columns of the through electrodes 243 on each side of the quadrangular ring shape, the number of columns of the through electrodes 243 on a side in a wiring line lead-out direction is larger than the number of columns of the through electrodes 243 on sides in the other directions. In the plan view of FIG. 9, given a downward direction of the pads 211P and 311P as a direction in which an end surface of the solid-state imaging device 1 is present and an upward direction as a direction in which the circuit regions 401A and 401B inside the substrate region are present, the wiring line lead-out direction in which the metal wiring lines 211 and 311 are led out from the pads 211P and 311P is the upward direction. Accordingly, for example, as depicted in FIG. 9, the number of columns of the through electrodes 243 is three on the side of the quadrangular ring shape in the upward direction, and the number of columns of the through electrodes 243 is two on the sides in leftward and rightward directions and on the side in the downward direction. Given that the wiring line lead-out direction refers to the two directions of the upward direction and the rightward direction, for example, the number of columns of the through electrodes 243 on the two sides of the upward direction and the rightward direction of the quadrangular ring shape is three, and the number of columns of the through electrodes 243 on the two sides of the downward direction and the leftward direction is two. The current flowing through the through electrodes 243 readily flows to the through electrodes 243 in the wiring line lead-out direction, and the through electrodes 243 are disposed such that the number of columns of the through electrodes 243 on the sides in the wiring line lead-out direction is larger than the number of columns on the sides in the other directions, making it possible to suppress electromigration due to current concentration. Further, an effect of reducing the IR drop is also achieved.

### 7. Variation Examples of Pad Structure

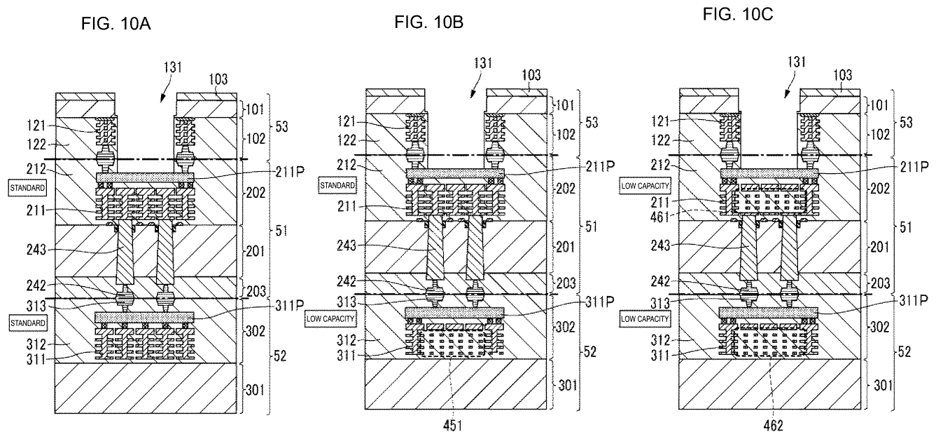

Next, variations of the pad structure connecting the pad 211P of the first substrate 51 and the pad 311P of the second substrate 52 will be described with reference to FIG. 10 to FIG. 12. In FIG. 10 to FIG. 12, portions corresponding to those of the embodiment and modification described above are denoted using the same reference signs, and description thereof will be omitted, as appropriate.

A of FIG. 10 is a cross-sectional view depicting, once again, the pad structure of the pad region 73 depicted in FIG. 4.

The pad structure of the first substrate 51 depicted in A of FIG. 10 is a structure obtained by disposing the plurality of layers of the metal wiring lines 211 below the pad 211P at high density. The pad Structure of the second substrate 52 is also a structure obtained by disposing the plurality of layers of the metal wiring lines 311 below the pad 311P at high density. By disposing the plurality of layers of the metal wiring lines 211 and 311 below the pads 211P and 311P at high density, it is possible to connect the pad 211P of the first substrate 51 and the pad 311P of the second substrate 52 with low resistance. Such a pad structure that realizes a low resistance connection is adopted for a power supply pad that supplies a power supply voltage, for example. Hereinafter, a pad structure obtained by disposing metal wiring lines below a pad at high density is referred to as a standard structure.

B of FIG. 10 is a cross-sectional view depicting a pad structure of a first variation.

The pad structure of the first substrate 51 depicted in B of FIG. 10 is a standard structure obtained by disposing the plurality of layers of the metal wiring lines 211 below the pad 211P at high density. On the other hand, the pad structure of the second substrate 52 is a low-capacitance pad structure in which the density of the plurality of layers of the metal wiring lines 311 in a region 451 indicated by a dashed line below the pad 311P is low, suppressing a wiring line capacitance to a low level.

C of FIG. 10 is a cross-sectional view depicting a pad structure of a second variation.

The pad structure of the first substrate 51 depicted in C of FIG. 10 is a low-capacitance pad Structure obtained by lowering the density of the plurality of layers of the metal wiring lines 211 in a region 461 indicated by a dashed line below the pad 211P. The pad structure of the second substrate 52 is also a low-capacitance pad structure obtained by lowering the density of the plurality of layers of the metal wiring lines 311 in a region 462 indicated by a dashed line below the pad 311P.

The pad structures of the first variation of B of FIG. 10 and the second variation of C of FIG. 10 can be adopted in a case in which, for example, a signal transmitted through the pads 211P and 311P is a high-speed signal and parasitic capacitance is desirably suppressed.

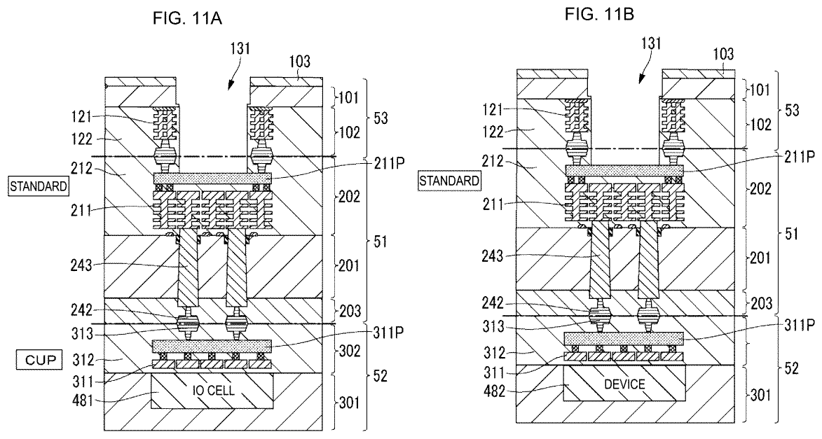

A of FIG. 11 is a cross-sectional view depicting a pad structure of a third variation.

The pad structure of the first substrate 51 depicted in A of FIG. 11 is a standard structure obtained by disposing the plurality of layers of the metal wiring lines 211 below the pad 211P at high density. On the other hand, the pad structure of the second substrate 52 is a circuit-under-pad (CUP) structure obtained by disposing a predetermined signal processing circuit in a region of the semiconductor substrate 301 below the pad 311P. As the predetermined signal processing circuit disposed below the pad 311P, an input/output cell (IO cell) 481 having an interface function with an external circuit or the like can be disposed, for example. By adopting the CUP structure as the pad structure of the second substrate 52, it is possible to increase a logic circuit mounting capacity of the second substrate 52. The CUP structure can be adopted whether the pads 211P and 311P are power supply pads or signal pads.

B of FIG. 11 is a cross-sectional view depicting a pad structure of a fourth variation.

The pad structure of the first substrate 51 depicted in B of FIG. 11 is a standard structure obtained by disposing the plurality of layers of the metal wiring lines 211 below the pad 211P at high density. On the other hand, the pad structure of the second substrate 52 is a structure obtained by disposing a device 482 in a region of the semiconductor substrate 301 below the pad 311P, the device 482 being any of various devices such as a transistor, a diode, a capacitor, or a resistor. For example, in a case in which power supply fluctuation is desirably suppressed, a decoupling capacitor (DECAP) is disposed as the device 482. A power gate transistor may be disposed as the device 482.

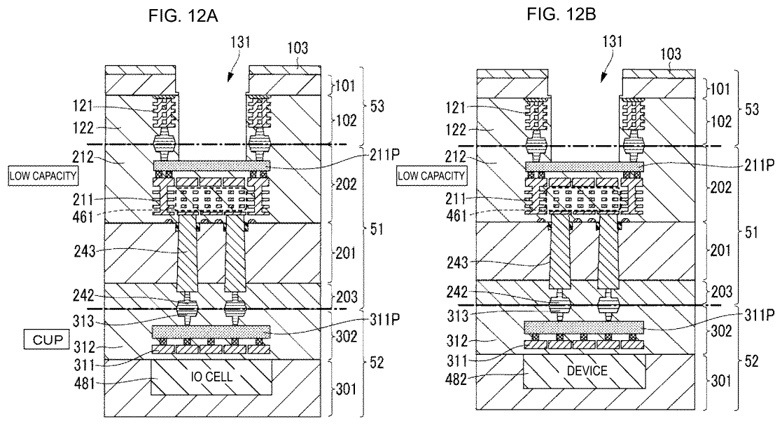

A of FIG. 12 is a cross-sectional view depicting a pad structure of a fifth variation.

The pad structure of the first substrate 51 depicted in A of FIG. 12 is a low-capacitance pad Structure obtained by lowering the density of the plurality of layers of the metal wiring lines 211 in the region 461 indicated by the dashed line below the pad 211P. On the other hand, the pad structure of the second substrate 52 is a CUP structure obtained by disposing the predetermined signal processing circuit 481 in a substrate region below the pad 311P. A case in which the low-capacitance pad structure and the CUP structure are combined is effective in a case in which a signal transmitted through the pads 211P and 311P is a high-speed signal and the logic circuit mounting capacity of the second substrate 52 is desirably increased, or a case in which a chip size is desirably minimized.

B of FIG. 12 is a cross-sectional view depicting a pad structure of a sixth variation.

The pad structure of the first substrate 51 depicted in B of FIG. 12 is a low-capacitance pad Structure obtained by lowering the density of the plurality of layers of the metal wiring lines 211 of the region 461 indicated by the dashed line below the pad 211P. On the other hand, the pad structure of the second substrate 52 is a structure obtained by disposing the device 482 in a substrate region below the pad 311P, the device 482 being any of various devices. A power gate transistor may be disposed as the device 482. For example, in a case in which power supply fluctuation is desirably suppressed, a decoupling capacitor is disposed as the device 482.

### 8. Summary of Pad Structure of Present Disclosure

The pad structure of the present disclosure includes the first substrate 51 including the first pad (pad 211P) and the first semiconductor substrate (semiconductor substrate 201) and the second substrate 52 including the second pad (pad 311P) and the second semiconductor substrate (semiconductor substrate 301) and is configured such that the first substrate 51 and the second substrate 52 are layered in the vertical direction, and the first pad and the second pad are disposed in regions overlapping in a plan view. Further, the plurality of through electrodes 243 penetrating the first semiconductor substrate and electrically connecting the first pad and the second pad are disposed in a ring shape in a plan view.

The solid-state imaging device 1 may be configured by, for example, integrating the circuit configuration of the pixel 21 depicted in FIG. 2 into the first substrate 51 and forming a layered structure of two substrates of the first substrate 51 and the second substrate 52 described above.

Alternatively, the solid-state imaging device 1 may be constituted of a layered structure of four substrates, and the configuration of the pad 211P of the first substrate 51, the pad 311P of the second substrate 52, and the plurality of through electrodes 243 described above may be applied to two of the four substrates, the two substrates being bonded to each other.

### 9. Usage Example of Image Sensor

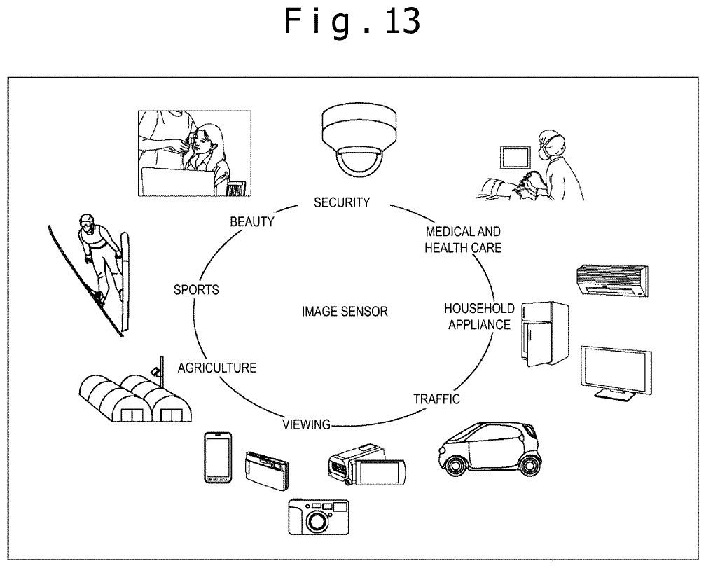

FIG. 13 is a diagram depicting a usage example of a case in which the solid-state imaging device 1 described above is used as an image sensor.

The solid-state imaging device 1 can be used as an image sensor in various cases of sensing light such as visible light, infrared light, ultraviolet light, and X-rays, for example, as follows.
A device for imaging an image used for viewing purposes, such as a digital camera or a portable device with a camera function.
A device for traffic use, such as in-vehicle sensor for imaging images of the front, rear, surrounding, inside, and the like of an automobile, a monitoring camera that monitors a traveling vehicle and a road, and a distance measurement sensor that measures a distance between vehicles and the like, for safe driving such as automatic stop, for recognition of a driver state, and the like
A device for use in household electrical appliances, such as a TV, a refrigerator, and an air conditioner, to image a gesture of a user and operate the device according to the gesture
A device for medical and healthcare use, such as an endoscope, and a device for performing angiography by receiving infrared light
A security device, such as a surveillance camera for crime prevention and a camera for person authentication
A device for beauty care, such as a skin measuring instrument for imaging skin and a microscope for imaging a scalp
A device used for sports, such as an action camera or a wearable camera for sports applications and the like
A device for agricultural use, such as a camera for monitoring the condition of a field or crop

### 10. Application Example of Electronic Apparatus

The technology of the present disclosure is not limited to application to the solid-state imaging device. That is, the technology of the present disclosure is applicable to general electronic apparatuses that use a solid-state imaging device in an image capturing section (photoelectric conversion section), such as an imaging device such as a digital still camera or a video camera, a portable terminal device having an imaging function, or a copying machine that uses a solid-state imaging device in an image readout section. The solid-state imaging device may be formed as one chip, or may be formed as a module having an imaging function in which an imaging section and a signal processing unit or an optical system are collectively packaged.

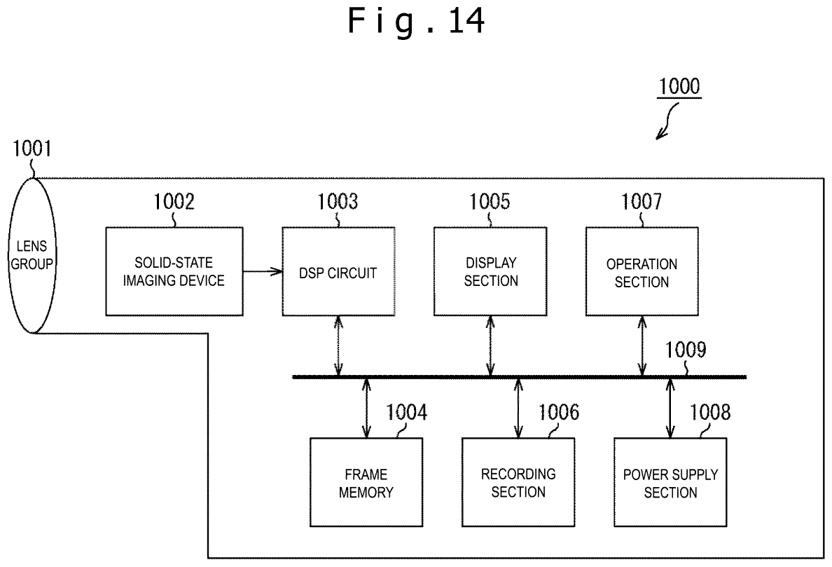

FIG. 14 is a block diagram depicting a configuration example of an imaging device as an electronic apparatus to which the technology of the present disclosure is applied.

An imaging device 1000 in FIG. 14 includes an optical section 1001 including a lens group and the like, a solid-state imaging device (imaging device) 1002 in which the configuration of the solid-state imaging device 1 in FIG. 1 is adopted, and a digital signal processor (DSP) circuit 1003 that is a camera signal processing circuit. The imaging device 1000 also includes a frame memory 1004, a display section 1005, a recording section 1006, an operation section 1007, and a power supply section 1008. The DSP circuit 1003, the frame memory 1004, the display section 1005, the recording section 1006, the operation section 1007, and the power supply section 1008 are connected to each other via a bus line 1009.

The optical section 1001 captures incident light (image light) from a subject and forms an image on an imaging surface of the solid-state imaging device 1002. The solid-state imaging device 1002 converts the amount of incident light imaged on the imaging surface by the optical section 1001 into an electric signal in units of pixels and outputs the electric signal as a pixel signal. As this solid-state imaging device 1002, it is possible to use the solid-state imaging device 1 described above, that is, a solid-state imaging device configured by layering the third substrate 53, the first substrate 51, and the second substrate 52 in the vertical direction with the opening 131 of the third substrate 53, the pad 211P of the first substrate 51, and the pad 311P of the second substrate 52 formed in regions overlapping in a plan view.

The display section 1005 is configured by a thin display such as a liquid crystal display (LCD) or an organic electro-luminescence (EL) display, for example, and displays a moving image or a still image imaged by the solid-state imaging device 1002. The recording section 1006 records the moving image or the still image imaged by the solid-state imaging device 1002 in a recording medium such as a hard disk or a semiconductor memory.

The operation section 1007 issues operation commands for various functions of the imaging device 1000 under the operation of the user. The power supply section 1008 appropriately supplies various power supplies serving as operation power supplies of the DSP circuit 1003, the frame memory 1004, the display section 1005, the recording section 1006, and the operation section 1007 to these supply targets.

As described above, by using the solid-state imaging device 1 described above as the solid-state imaging device 1002, it is possible to secure a wide circuit region and reduce the IR drop and signal delay.

Further, it is possible to suppress electromigration due to current concentration and improve the reliability of product quality. Size reduction and higher quality imaging of an imaged image can be achieved even in the imaging device 1000 such as a video camera, a digital still camera, or a camera module for a mobile device such as a mobile telephone.

### 11. Application to General Light Detection Device

Although an example in which the technology of the present disclosure is applied to a solid-state imaging device that outputs an image signal has been described in the example above, the technology of the present disclosure can be applied not only to the solid-state imaging device but also to light detection devices in general that include pixels that receive incident light and photoelectrically convert the incident light. For example, the technology of the present disclosure can be applied to a light-receiving device (distance measurement sensor) of a distance measurement system that receives infrared light emitted as active light and measures a distance to a subject by a direct ToF method or an indirect ToF method. Further, application is not limited to the CMOS type solid-state imaging device, and can be made to a charge coupled device (CCD) type solid-state imaging device.

### 12. Application Example of Mobile Body

The technology according to the present disclosure (present technology) can be applied to various products. For example, the technology according to the present disclosure may be realized as a device mounted on any type of mobile body such as an automobile, an electric vehicle, a hybrid electric vehicle, a motorcycle, a bicycle, a personal mobility, an airplane, a drone, a ship, and a robot.

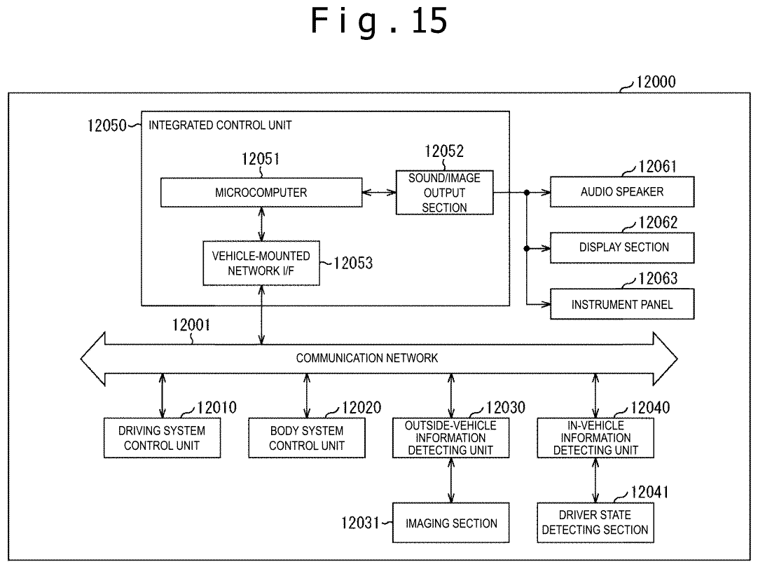

FIG. 15 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 15, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the Steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the Steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 15, an audio speaker 12061, a display section 12062, and an instrument panel 12063 are illustrated as the output device. The display section 12062 may, for example, include at least one of an on-board display and a head-up display.

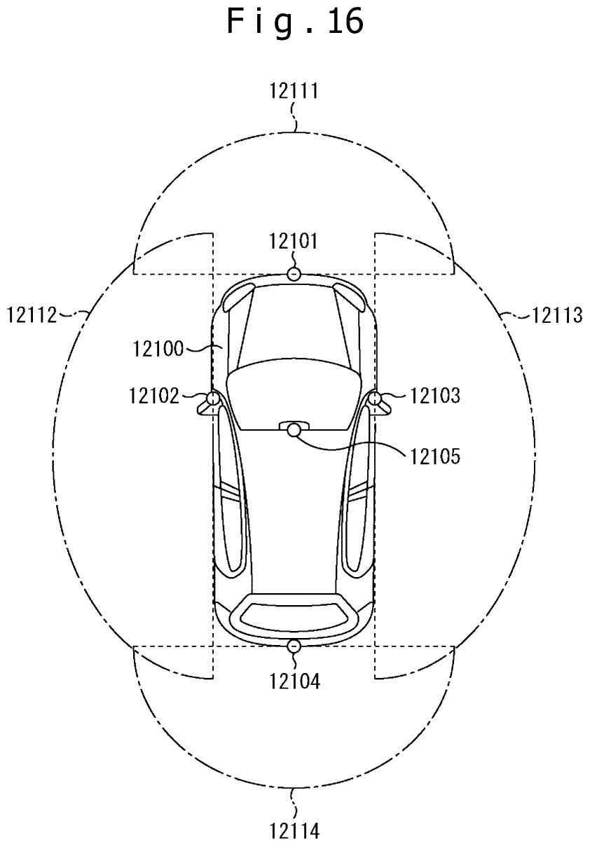

FIG. 16 is a diagram depicting an example of the installation position of the imaging section 12031.

In FIG. 16, a vehicle 12100, as the imaging section 12031, includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The images of the front acquired by the imaging sections 12101 and 12105 are mainly used to detect a preceding vehicle, a pedestrian, an obstacle, a traffic light, a traffic sign, a lane, or the like.

Incidentally, FIG. 16 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been described above. The technology according to the present disclosure can be applied to the imaging section 12031 among the configurations described above. Specifically, the solid-state imaging device 1 described above can be applied as the imaging section 12031. By applying the technology according to the present disclosure to the imaging section 12031, it is possible to obtain an imaged image that is easier to view and to acquire distance information while reducing the size. Further, it is possible to reduce the fatigue of the driver and to enhance the safety of the driver and the vehicle by using the obtained imaged image and distance information.

Further, the present disclosure is not limited to application to a solid-state imaging device that detects a distribution of an incident light amount of visible light and images the distribution as an image, and can be applied to a solid-state imaging device that images a distribution of an incident amount of infrared rays, X-rays, particles, or the like as an image or, in a broad sense, to a solid-state imaging device (physical quantity distribution detection device) in general such as a fingerprint detection sensor that detects a distribution of another physical quantity such as pressure or electrostatic capacitance and images the distribution as an image.

In addition, the technology of the present disclosure is applicable, in addition to the solid-state imaging device, to semiconductor devices in general including other semiconductor integrated circuits.

The embodiments of the present disclosure are not limited to the embodiments described above, and various modifications can be made without departing from the gist of the technology of the present disclosure.

Note that the effects described in the present specification are merely examples and are not limited, and effects other than those described in this specification may be provided.

Note that the technology of the present disclosure can also adopt the following configurations.

(1)

A solid-state imaging device including:
a first substrate including a first pad and a first semiconductor substrate; and
a second substrate including a second pad and a second semiconductor substrate,
wherein the solid-state imaging device is configured such that the first substrate and the second substrate are layered in a vertical direction, and
a plurality of through electrodes penetrating the first semiconductor substrate and electrically connecting the first pad and the second pad are disposed in a ring shape in a plan view.
   (2)

The solid-state imaging device according to (1),
wherein the plurality of through electrodes are disposed in a plurality of columns in the ring shape, the ring shape being a quadrangular shape, and
the number of columns of the plurality of through electrodes on, among sides of the quadrangular shape, a side in a wiring line lead-out direction is greater than the number of columns of the plurality of through electrodes on sides in other directions.
   (3)

The solid-state imaging device according to (1) or (2),
wherein the first pad and the second pad are electrically connected to each other via the plurality of through electrodes and metal bonding that bonds the first substrate and the second substrate.
   (4)

The solid-state imaging device according to any one of (1) to (3),
wherein the first pad and the second pad are disposed in regions overlapping in a plan view.
   (5)

The solid-state imaging device according to any one of (1) to (4),
wherein the first substrate includes a first pad region in which a plurality of the first pads are disposed,
the second substrate includes a second pad region in which a plurality of the second pads are disposed, and
the first pad region and the second pad region are regions overlapping in a plan view.
   (6)

The solid-state imaging device according to any one of (1) to (5),
wherein the second substrate includes a plurality of layers of metal wiring lines and an insulating layer between the second pad and the second semiconductor substrate.
   (7)

The solid-state imaging device according to any one of (1) to (6),
wherein the second substrate includes a predetermined signal processing circuit in a region of the second semiconductor substrate below the second pad.
   (8)

The solid-state imaging device according to any one of (1) to (7),
wherein the second substrate includes a predetermined device in a region of the second semiconductor substrate below the second pad.
   (9)

The solid-state imaging device according to any one of (1) to (8), further including:
a light-receiving substrate that is a semiconductor substrate including a photoelectric conversion section,
wherein the solid-state imaging device is configured such that the light-receiving substrate is further layered on a side of the first substrate opposite to the second substrate side, and
an opening of the light-receiving substrate, the first pad of the first substrate, and the second pad of the second substrate are disposed in regions overlapping in a plan view.
   (10)

An electronic apparatus including:
a solid-state imaging device including
a first substrate including a first pad and a first semiconductor substrate, and
a second substrate including a second pad and a second semiconductor substrate,
the solid-state imaging device being configured such that the first substrate and the second substrate are layered in a vertical direction, and
a plurality of through electrodes penetrating the first semiconductor substrate and electrically connecting the first pad and the second pad being disposed in a ring shape in a plan view.

### REFERENCE SIGNS LIST

1 Solid-state imaging device, 11 Pixel array section, 21 Pixel, 51 First substrate, 52 Second substrate, 53 Third substrate, 61 Light-receiving pixel, 62 Light-receiving region, 71 Readout circuit, 72 Readout region, 73, 73A, 73B Pad region, 101 Semiconductor substrate, 102 Wiring layer, 121 Metal wiring line, 122 Insulating layer, 123 Bonding electrode, 131 Opening, 201 Semiconductor substrate, 202 Wiring layer, 203 Bonding layer, 211 Metal wiring line, 211C Metal wiring line, 211P Pad, 212 Insulating layer, 213 Bonding electrode, 241 Insulating layer, 242 Bonding electrode, 243 Through electrode, 301 Semiconductor substrate, 302 Wiring layer, 303 Protective film, 311 Metal wiring line, 311C Metal wiring line, 311P Pad, 312 Insulating layer, 313 Bonding electrode, 481 Processing circuit, 482 Device, 1000 Imaging device, 1002 Solid-state imaging device

1. A solid-state imaging device comprising:
a first substrate including a first pad and a first semiconductor substrate; and
a second substrate including a second pad and a second semiconductor substrate,
wherein the solid-state imaging device is configured such that the first substrate and the second substrate are layered in a vertical direction, and
a plurality of through electrodes penetrating the first semiconductor substrate and electrically connecting the first pad and the second pad are disposed in a ring shape in a plan view.

2. The solid-state imaging device according to claim 1,
wherein the ring shape is a quadrangular shape with an empty region in a central portion of the ring shape, and
the plurality of through electrodes are disposed in a plurality of columns on each side of the quadrangular shape and disposed such that the number of columns of the plurality of through electrodes on, among the sides of the quadrangular shape, a side in a wiring line lead-out direction is greater than the number of columns of the plurality of through electrodes on sides in other directions.

3. The solid-state imaging device according to claim 1,
wherein the first pad and the second pad are electrically connected to each other via the plurality of through electrodes and metal bonding that bonds the first substrate and the second substrate.

4. The solid-state imaging device according to claim 1,
wherein the first pad and the second pad are disposed in regions overlapping in a plan view.

5. The solid-state imaging device according to claim 1,
wherein the first substrate includes a first pad region in which a plurality of the first pads are disposed,
the second substrate includes a second pad region in which a plurality of the second pads are disposed, and
the first pad region and the second pad region are regions overlapping in a plan view.

6. The solid-state imaging device according to claim 1,
wherein the first substrate includes a plurality of layers of metal wiring lines and an insulating layer between the first pad and the first semiconductor substrate, and
the second substrate includes a plurality of layers of metal wiring lines and an insulating layer between the second pad and the second semiconductor substrate.

7. The solid-state imaging device according to claim 1,
wherein the second substrate includes a predetermined signal processing circuit in a region of the second semiconductor substrate below the second pad.

8. The solid-state imaging device according to claim 1,
wherein the second substrate includes a predetermined device in a region of the second semiconductor substrate below the second pad.

9. The solid-state imaging device according to claim 1, further comprising:
a light-receiving substrate that is a semiconductor substrate including a photoelectric conversion section,
wherein the solid-state imaging device is configured such that the light-receiving substrate is further layered on a side of the first substrate opposite to the second substrate side, and
an opening of the light-receiving substrate, the first pad of the first substrate, and the second pad of the second substrate are disposed in regions overlapping in a plan view.

10. An electronic apparatus comprising:
a solid-state imaging device including
a first substrate including a first pad and a first semiconductor substrate, and
a second substrate including a second pad and a second semiconductor substrate,
the solid-state imaging device being configured such that the first substrate and the second substrate are layered in a vertical direction, and
a plurality of through electrodes penetrating the first semiconductor substrate and electrically connecting the first pad and the second pad being disposed in a ring shape in a plan view.
